(19) United States
(12) Patent Application Publication
(10) Pub. No.: US 2026/0110642 A1
(43) Pub. Date: Apr. 23, 2026

(54) INTERFEROMETER IN OPTOELECTRONIC PACKAGE

(71) Applicant: GPD Optoelectronics Corp., Salem, NH (US)

(72) Inventors: David T. Beatson, Plymouth, MI (US); Youngsik Kim, Tucson, AZ (US); Peter E. Dixon, Bedford, NH (US)

(73) Assignee: GPD Optoelectronics Corp., Salem, NH (US)

(21) Appl. No.: 19/358,640

(22) Filed: Oct. 15, 2025

Related U.S. Application Data
(60) Provisional application No. 63/708,382, filed on Oct. 17, 2024.

(51) Int. Cl. G01N 21/95; H10F 55/255

(52) U.S. Cl. CPC G01N 21/9501; H10F 55/255; G01N 2201/06113

(57) ABSTRACT

An optoelectronic package for measuring distance, tip, and tilt of an object relative to a detector. The optoelectronic package comprises a carrier; a photodiode element (photodiode elements) located on the carrier and having a center opening; a vertical-cavity surface-emitting laser (VCSEL) located in the center opening and directing light rays toward the object; and an interference generating optical element positioned between the photodiode element and the object. Light passes through the optical element from the VCSEL creating a ring of measured light which reflects off the surface of the object and combines with a ring of reflecting reference light to produce interference fringes on the photodediode elements with varying light intensity, which correspond to displacement and angular tip and tilt of the surface of the object. The measurement of these variations will be interpreted by a computational element to produce a value of distance, tip, and tilt of the object.

### CROSS REFERENCE TO RELATED APPLICATIONS

This application claims the benefit of priority to U.S. Provisional Patent Application Ser. No. 63/708,382 filed on Oct. 17, 2024, the contents of which are incorporated in this application by reference.

### TECHNICAL FIELD

The present disclosure relates generally to optoelectronic devices and, more particularly, to a photodiode element used in combination with a laser and optics to form an interferometer within an optoelectronic package.

### BACKGROUND OF THE DISCLOSURE

Photodiode elements are essential in semiconductor manufacturing for various quality control, process monitoring, and measurement applications. Overall, photodiode elements are crucial for maintaining the precision and quality of semiconductor manufacturing processes. They provide valuable feedback that helps optimize and control various steps in the production cycle. More specifically, photodiode elements are used to inspect wafers, in the photolithography process, in alignment and overlay control, in metrology, to monitor processes, and to facilitate end-of-line testing.

Photodiode elements help in inspecting semiconductor wafers for defects. They can detect surface imperfections or contamination by measuring reflected or transmitted light. This is crucial for ensuring that the wafers meet the stringent quality standards required for semiconductor devices. In the photolithography process, a photodiode element can monitor the exposure of photoresist material on the wafer. This involves measuring the intensity of light that passes through photomasks to ensure that the correct patterns are being transferred onto the wafer.

Photodiode elements are used in alignment systems to ensure that different layers of the semiconductor devices are accurately aligned. They detect and measure light patterns to help align masks and wafers precisely during the fabrication process. In semiconductor metrology, photodiode elements are used to measure critical dimensions and other parameters of semiconductor features. They can be part of tools that perform optical measurements to ensure that features are manufactured to the correct specifications. During various fabrication steps, such as chemical vapor deposition (CVD) or etching, photodiode elements can monitor the process in real-time. For example, they might measure the intensity of light emitted during a plasma process to monitor process stability and quality. After the semiconductor devices are manufactured, photodiode elements can be used to test and characterize the final products. Such use includes checking for electrical and optical properties to ensure that the devices perform as intended.

As explained in an article by R. Paschotta titled “Position-Sensitive Detectors,” available at https://www.rp-photonics.com/position_sensitive_detectors.html and accessed on May 16, 2023, position-sensitive detectors are photodiode elements with which one can measure the position of a light spot (or, as disclosed in U.S. Pat. No. 11,424,827 titled “Optical Tracking System,” a non-spot impingement on the photodiode element, such as those impingements illustrated in FIG. 9 of the patent, created by a non-spot beam shape) in one or two dimensions, normally with a relatively high speed. The light spot is usually caused by a laser beam hitting the photodiode element. Such photodiode elements can be used to monitor beam position and, therefore, optical system alignment (laser spot trackers). Another application is (within a feedback system) to stabilize the position of a laser beam (auto aligners). Still another application is to measure distances by triangulation.

Position-sensitive detectors can be based on different operation principles. One measurement principle for position sensing is to use a kind of segmented photodiode element, which can measure optical intensities for a few or even multiple photodiode configurations. From the resulting data, the position of the light spot can be calculated. The uniformity of response between different detector segments is of course an important quality feature of such devices.

In the simplest case, as illustrated in FIG. 1, a photodiode 10 with two active segments, sections, or detectors 12 and 14 (a dual-segment photodiode or dual-cell photodiode) is used, with a narrow gap 16 between them. The incident beam forms a light spot 18 on the photodiode 10. The beam radius of the incident beam is chosen such that at least for beam positions in the intermediate range both detectors 12, 14 obtain some optical power. FIG. 2 is a graph depicting the output signals from the photodiode 10 with two signals as functions of the beam position. From the relative signals related to the two detectors 12, 14 (the detector 12 is the “left” detector and the detector 14 is the “right” detector) the beam position can be calculated. The gap 16 between the adjacent detectors 12, 14 is a transition region. The device design ultimately determines whether charge can be collected from light incident upon the transition zone (“gap”), where charge may be shared across multiple devices, or there may be a reduction in signal, or changed optical performance. Thus, the segmented device may result in perturbations or may result in “blind spots” or areas in which no output signal is produced by incident light.

Note that for this kind of device one obtains a nonlinear dependence of the signal on the position; therefore, a linearization technique may have to be applied. In addition, the relative intensities depend not only on the beam position, but also on the beam radius. For those reasons, such segmented diodes are not ideally suited for quantitative position measurements. They are useful, however, for checking whether a beam is properly centered (centering indicators), e.g., within a feedback system for automatic alignment. For example, such devices are used in devices for optical data storage (CD-ROM, DVD, etc.).

Similarly, one can use a quadrant photodiode 20 with four active segments, sections, or detectors 22, 24, 26, and 28 having a narrow gap 30 between them as shown in FIG. 3. The incident beam forms a light spot 18 on the quadrant photodiode 20. The quadrant photodiode 20 can be used to monitor positions in two dimensions. For further information about the quadrant photodiode 20, see D. Marett, “A Four Quadrant Photo Detector for Measuring Laser Pointing Stability,” available at https://www.conspiracyoflight.com (2012).

Segmented photodiodes like the photodiode 10 and the quadrant photodiode 20 are often based on silicon PIN technology, with sensitivity in the visible spectral range and up to about 1 μm. (They are also available with other semiconductors, however, such as indium gallium arsenide (InGaAs) for detection at longer infrared wavelengths.) The quadrant photodiode 20 often consists of four separate P on N silicon photosensitive surfaces separated by the small gap 30. In one example, the gap 30 is about 42 μm. The laser beam is usually pointed towards the dead center among the four quadrants and the beam diameter is selected to fit inside of the total quadrant area. Although light may fall on all four quadrants, the difference between the left and right quadrants (X output) and the top and bottom quadrants (Y output) can be adjusted to zero by centering the beam, whereas the SUM is at a maximum. The device X and Y output voltages thereby become very sensitive to slight deviations in the position of the beam from this initial centered setting. On the other hand, the SUM value can be used to measure changes in the beam intensity, so this can be used to correct the X and Y output values for voltage changes that are due to intensity fluctuations rather than actual beam deviations. In order to present the outputs of the four quadrants as X, Y, and SUM, it is necessary to first amplify the individual quadrant outputs, and then combine them using a series of sum and difference amplifiers (for X and Y) or just a sum amplifier (for the SUM output). Further, the spot size and location determine whether a signal can be collected from more than one pixel element. If in some instances light is fully within one single pixel, with no light incident upon a gap or another pixel, this can cause ambiguity as to spot location, causing the system to raster, slew, or “search” for the precise location of the beam.

As illustrated in FIG. 4, the PIN diode 40 that forms the basis for segmented photodiodes like the photodiode 10 and the quadrant photodiode 20 is an alteration of the PN-junction diode having an area A. Unlike the PN-junction diode, the PIN diode 40 has an undoped, wide intrinsic semiconductor region 44 (with a width W) between a P-type semiconductor region 42 and an N-type semiconductor region 46. Thus, the PIN diode 40 has three regions: namely, the P-region 42, the I-region 44, and the N-region 46. The P and N regions 42, 46 are normally heavily doped because they are used for Ohmic contacts. The inclusion of the intrinsic region 44 in the PIN diode 40 can significantly increase the breakdown voltage for the application of high voltage. The intrinsic region 44 also offers advantageous properties when the PIN diode 40 operates at high frequencies in the range of radio waves and microwaves.

The working principle of the PIN diode 40 is exactly the same as the PN-junction diode. The main difference is that the depletion region, which normally exists between the P and N regions 42, 46, is larger. In any PN-junction diode, the P region 42 has been doped to contain holes. Likewise, the N-region 46 has been doped to have excess electrons. The intrinsic region 44 between the P and N regions 42, 46 includes no charge carriers because any electrons or holes merge. Therefore, the depletion region functions as an insulator. FIG. 5 outlines the structure of the PIN diode 40. One application of the PIN diode 40 is use as a photodiode element to convert light (optical signals) into current (electrical signals).

Segmented photodiodes are also known having more complex arrays than the two active segments, sections, or detectors of the photodiode 10 and the four active segments, sections, or detectors of the quadrant photodiode 20. There are photodiode arrays containing a larger number of photodiode segments either in a linear array for one-dimensional position sensing or on a two-dimensional grid. Such devices can contain hundreds or thousands of diodes. In principle, one could derive the spot position simply by taking the coordinates of the pixel (detector segment) receiving the highest optical power. The spatial resolution would then be identical to the pixel spacing. A much better resolution can be achieved by using data from several pixels, assuming that the light spot 18 is large enough. For example, one may fit a calculated curve to the pixel data, calculating the position and the beam radius as fit parameters. A computationally simpler approach is to calculate the centroid via first moments of the intensity distribution, possibly after discarding pixels which have intensity values below a certain threshold value or are spatially too far away from the intensity maximum.

One example of segmented photodiodes having a more complex array is disclosed in FIG. 6, which illustrates a known InGaAs PIN double quadrant photodiode element 50 having eight independent active-area sections, segments, or detectors. The double quadrant photodiode element 50 is available from Princeton Lightwave, Inc. of Cranbury, New Jersey. As illustrated, the eight-section double quadrant photodiode element 50 has four inner quadrant sections 52 and four outer quadrant sections 54. The hermetically sealed packaging for the double quadrant photodiode element 50 is a T0-8 through-hole metal can with an anti-reflection coated window cap (not shown) and twelve pins, terminals, or leads 56. Eight leads 56 connect the sections 52, 54 of the inner and outer quadrants of the double quadrant photodiode element 50 to respective bond pads 58, and the remaining four leads are connected to the common cathode (substrate) of the detectors. (Neither the remaining four leads nor the cathode are shown in FIG. 6.) All twelve leads are isolated from the package case. The common cathode connection is made to each center pin of each of the four groups of three in-line pins. The overall detector optically active diameter, D, is typically 1 mm.

Another example of segmented photodiodes having a more complex array is disclosed in U.S. Pat. No. 3,689,772 titled “Photodiode element Light Pattern Detector.” The array includes first and second semi-circular sub-arrays. The first sub-array has a plurality (i.e., eight) of concentric annular detectors, such as hemi-rings. The second sub-array has a plurality (i.e., thirty four) of detectors extending approximately radially from near to the center of the first sub-array. Each detector of the array is provided with a separate attached electrical conductor. The conductors attached to the ring detectors are positioned in portions of approximately radial sector gaps separating the two sub-arrays.

Yet another example of segmented photodiodes having a more complex array is disclosed in U.S. Pat. No. 11,646,384 titled “Optoelectronic Devices With Non-Rectangular Die Shapes.” FIG. 7 of the patent is a top plan view illustration of multiple photodiodes within a detector assembly. More specifically, the photodiodes may be non-rectangular shaped, such as a trapezoid, and can be further arranged in configurations that increase surface area use.

Despite these attempts, a need exists to improve photodiode elements for use in semiconductor manufacturing by enhancing their performance, reliability, and integration with advanced technologies. Therefore, an object of the present disclosure is to enhance the sensitivity and resolution of photodiode elements allowing for more precise measurements and detection of smaller defects or finer features. Another object is to achieve the faster response times that are crucial for real-time monitoring and high-throughput manufacturing processes. Yet another object is to reduce noise levels in photodiode elements which is essential for accurate measurements, particularly in low-light conditions or high-precision applications. A further object is to provide a photodiode element that provides improved durability and reliability through advanced packaging and protective coatings so that consistent performance is ensured over long periods despite the harsh environments, such as high radiation or extreme temperatures, of some semiconductor processes. It is also an object of the present disclosure to reduce the power consumption of photodiode elements which is important for minimizing operational costs and managing heat in semiconductor manufacturing environments.

### SUMMARY OF THE DISCLOSURE

To meet this and other needs, to achieve these and other objects, and in view of its purposes, the present disclosure provides an optoelectronic package for measuring the surface of an object such as a semiconductor wafer or a motion system within a semiconductor tool. The optoelectronic package comprises a carrier such as a leadless chip carrier; a photodiode element located on the leadless chip carrier and having a center opening; a vertical-cavity surface-emitting laser (VCSEL) located in the center opening of the photodiode element and directing light rays toward the object; and an interferometer positioned between the VCSEL and the object. The interferometer receives the light rays from the VCSEL and creates a ring of measured light which reflects off the surface of the object and combines with a ring of reference light to produce interference fringes on the photodiode element so that the photodiode element sees varying light intensity due to optical interference. The variations in light intensity correspond to displacement and angular tip and tilt of the surface of the object.

In certain embodiments, an optical detection system comprising at least one light source, an optical assembly configured to direct light from the light source to a target, and a photodiode element arrangement, such as photodiode element, positioned to receive light reflected or transmitted from the target. The photodiode element may be implemented as a single photodiode, a segmented detector, or a focal plane array, and is operatively coupled to processing electronics for generating output signals indicative of the received light. The system may further include a computer system, which is configured to process the output signals from the photodiode element to determine one or more characteristics of the target, such as position, displacement, or surface profile. This arrangement enables precise optical measurements and can be adapted for a variety of applications, including metrology, imaging, and alignment.

In certain embodiments, the optical detection system includes a photodiode element arrangement implemented as a focal plane array, with a black mask disposed over the array to define one or more apertures for controlled light reception. This configuration enables precise spatial resolution and improved signal discrimination by limiting the regions of the focal plane array that are exposed to incident light, thereby reducing stray light and enhancing measurement accuracy. The system further comprises at least one light source, an optical assembly for directing light to a target, processing electronics for generating output signals from the photodiode element, and a computer system configured to analyze these signals and determine characteristics of the target. The integration of a black mask with the focal plane array provides additional flexibility in tailoring the detection geometry to specific application requirements, supporting advanced optical measurement and imaging techniques.

In other embodiments, the invention encompasses a method of operating an optical detection system, wherein light from a source is directed to a target via an optical assembly, and light reflected or transmitted from the target is detected by a photodiode element arrangement, such as photodiode element. The method includes generating electrical signals corresponding to the detected light and processing these signals, for example using a computer system, to extract information about the target. The method may further include steps for calibrating the system, compensating for noise or background signals, and outputting measurement results for further analysis or display.

Still further provided is a related system and at least one computer-readable non-transitory storage media embodying software. The one or more computer-readable non-transitory storage media embodying software is operable when executed, in one embodiment, to perform a series of steps using the components of the optoelectronic package.

It is to be understood that both the foregoing general description and the following detailed description are exemplary, but are not restrictive, of the disclosure.

### BRIEF DESCRIPTION OF THE DRAWING

The disclosure is best understood from the following detailed description when read in connection with the accompanying drawing. Included in the drawing are the following figures:

FIG. 1 illustrates a conventional dual-segment photodiode with a light spot of a beam impinging on the photodiode;

FIG. 2 is a graph depicting the output signals from the photodiode illustrated in FIG. 1 with two signals as functions of the beam position;

FIG. 3 illustrates a conventional quadrant photodiode with a light spot impinging on the quadrant photodiode;

FIG. 4 provides an outline of a PIN diode;

FIG. 5 illustrates the structure of a PIN diode;

FIG. 6 illustrates a known InGaAs PIN quadrant photodiode element having eight independent active-area sections, segments, or detectors;

FIG. 7 illustrates an equivalent circuit for a single-element photodiode;

FIG. 8 illustrates an equivalent circuit for a one-dimensional position sensing device;

FIG. 9 illustrates one embodiment of an optical detector system according to the present disclosure including a photodiode element having an improved geometrical pattern or array of detectors with a single anode contact per detector;

FIG. 10 depicts the optical detector system illustrated in FIG. 9 with a light beam impinging on the photodiode element;

FIG. 11 illustrates another embodiment of the optical detector system according to the present disclosure including shorting links;

FIG. 12 illustrates yet another embodiment of the optical detector system according to the present disclosure including two anode contacts per detector in the radial wedge section of the array of detectors;

FIG. 13 is a diagram of a simple structure illustrating a vertical-cavity surface-emitting laser (VCSEL) as one suitable example of a light source;

FIG. 14 is a schematic of a Mirau interferometer;

FIG. 15 illustrates one example embodiment of the optical detector system according to the present disclosure including a photodiode element with a VCSEL instead of inner quadrant sections;

FIG. 16 illustrates another example embodiment of the optical detector system according to the present disclosure including a photodiode element with a VCSEL instead of inner quadrant sections;

FIG. 17 illustrates an embodiment of the optoelectronic package according to the present disclosure;

FIG. 18 illustrates another embodiment of the optoelectronic package including a black mask;

FIG. 19 illustrates a trace of the laser beam rays emitted by an example VCSEL in the optoelectronic package depicted in FIG. 18;

FIG. 20 illustrates another trace of the laser beam rays emitted by an example VCSEL used in the optoelectronic package shown in FIG. 18;

FIG. 20A depicts the interference pattern, created by the Mirau interferometer of the optoelectronic package depicted in FIG. 18, that appears on the measured surface of a wafer;

FIG. 20B depicts the interference pattern that appears on the surface of the Mirau interferometer;

FIG. 20C depicts the interference pattern that appears on the concentric arc sections of the photodiode element;

FIG. 21 repeats FIG. 20 and again illustrates another trace of the laser beam rays emitted by an example VCSEL used in the optoelectronic package depicted in FIG. 18;

FIG. 21A is a cross section of the interference pattern, created by the Mirau interferometer of the optoelectronic package depicted in FIG. 18, that appears on the measured surface of a wafer;

FIG. 21B is a cross section of the interference pattern that appears on the surface of the Mirau interferometer;

FIG. 21C is a cross section of the interference pattern that appears on the concentric arc sections of the photodiode element; and

FIG. 22 illustrates an example computer system for use as part of or in connection with the optoelectronic package according to the present disclosure.

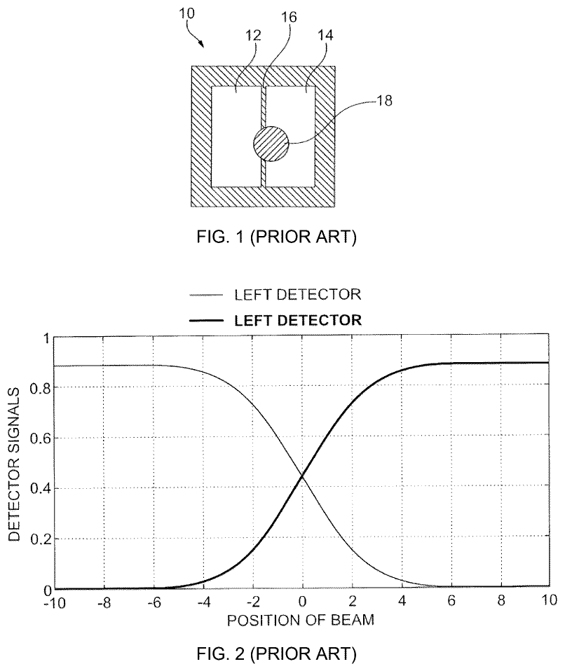

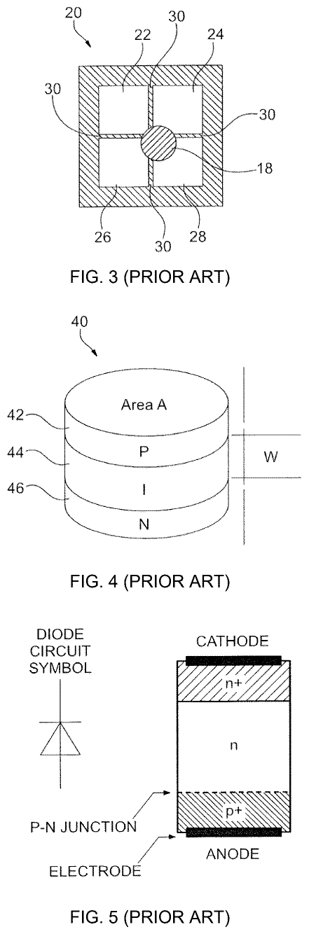

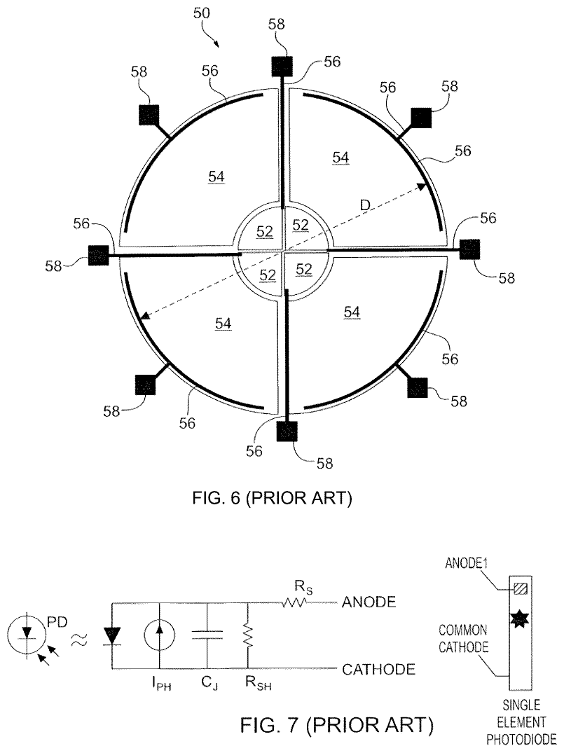

### DETAILED DESCRIPTION OF THE DISCLOSURE

In this specification and in the claims that follow, reference will be made to a number of terms which shall be defined to have the following meanings ascribed to them. The term “substantially,” as used in this document, is a descriptive term that denotes approximation and means “considerable in extent” or “largely but not wholly that which is specified” and is intended to avoid a strict numerical boundary to the specified parameter. Directional terms as used in this disclosure—for example up, down, right, left, front, back, top, bottom—are made only with reference to the figures as drawn and are not intended to imply absolute orientation.

The term “about” means those amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When a value is described to be about or about equal to a certain number, the value is within ±10% of the number. For example, a value that is about 10 refers to a value between 9 and 11, inclusive. When the term “about” is used in describing a value or an end-point of a range, the disclosure should be understood to include the specific value or end-point. Whether or not a numerical value or end-point of a range in the specification recites “about,” the numerical value or end-point of a range is intended to include two embodiments: one modified by “about” and one not modified by “about.” It will be further understood that the end-points of each of the ranges are significant both in relation to the other end-point and independently of the other end-point.

The term “about” further references all terms in the range unless otherwise stated. For example, about 1, 2, or 3 is equivalent to about 1, about 2, or about 3, and further comprises from about 1-3, from about 1-2, and from about 2-3. Specific and preferred values disclosed for components and steps, and ranges thereof, are for illustration only; they do not exclude other defined values or other values within defined ranges. The components and method steps of the disclosure include those having any value or any combination of the values, specific values, more specific values, and preferred values described.

The indefinite article “a” or “an” and its corresponding definite article “the” as used in this disclosure means at least one, or one or more, unless specified otherwise. “Include,” “includes,” “including,” “have,” “has,” “having,” comprise,” “comprises,” “comprising,” or like terms mean encompassing but not limited to, that is, inclusive and not exclusive.

### A. The Optical Detector System

The ability to transmit data wirelessly provides tremendous utility. Wireless transmission uses one or more frequencies of electromagnetic signals, such as optical wavelengths, to send information. Optical wavelengths may include, but are not limited to, infrared wavelengths, visible light wavelengths, ultraviolet wavelengths, and so forth. Optical wavelengths may move from one location to another in free space, including the atmosphere, a vacuum, and so forth.

Optical detector systems use an incoming beam with a beam shape that is typically (although not necessarily) circular in cross section, presenting a circular pattern (or “spot”) of light on the detector array. (A non-spot beam shape is a beam shape, where it impinges upon the detector array, that is non-circular in cross section.) The combined characteristics of the detector array and spot produce information about how much the output of the detector array changes in response to a change in the position of the light incident on the detector array. For example, the information describes how amplitude of an output signal from the photodiode elements in the array changes as the spot moves across the detector array.

The accuracy of the information is affected by several factors. One factor is how much of the incoming beam of light that impinges on the detector array produces output. The portion of the beam that impinges on photodiode elements in the array produces output. The portion of light that impinges on gaps between or among the photodiode elements does not. For example, if the spot of light falls entirely within a gap between photodiode elements, no output is produced.

The optical detector system provides output that is indicative of a relative position of an incoming beam of light relative to the detector array as well as distance of the incoming beam of light relative to the detector array. This output may then be used to operate one or more devices to provide active tracking of a beam of incoming light. The system may be used in a variety of applications including, but not limited to, intersatellite communications, communications between a satellite and ground station, communications between a satellite and user terminals, between vehicles, between terrestrial stations, and the like. For example, the system may be used in terrestrial applications, mobile applications, and so forth. Some of the applications are described in U.S. Pat. No. 11,424,827, mentioned above, which is incorporated by reference in this document.

Conventional optical detector systems use a single element as discussed above. FIG. 7 illustrates an equivalent circuit for a single-element photodiode (PD). The single-element PD has two terminals: a single, discrete anode located on one surface of the PD (on which an illuminated spot impinges) and a common cathode that extends substantially along the entire opposite surface of the PD. The single-element PD is position ambiguous.

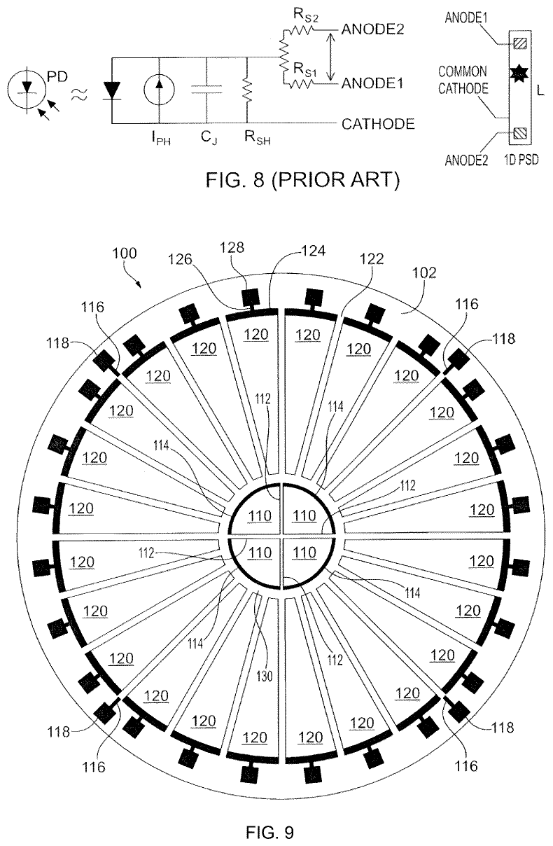

FIG. 8 illustrates an equivalent circuit for a one-dimensional position sensing device (1D PSD). The 1D PSD has three terminals: two, discrete anodes located on one surface of the 1D PSD (on which an illuminated spot impinges) and a common cathode that extends substantially along the entire opposite surface of the 1D PSD. Both anodes reference the same cathode. The 1D PSD is able to provide positional data in a single axis, typically within a single pixel. For a photonic 1D PSD, the position is relative to the location of the illuminated spot. The longitudinal position X is measured by the ratio I₁:I₂, where I₁ is the current in Anode 1 and I₂ is the current in Anode 2. More specifically, if L is the distance between the two anodes, the applicable formula is:

$$( {I}_{2} - {I}_{1} ) / ( {I}_{2} + {I}_{1} ) = 2 X / L .$$

The optical detector system 100 according to the present disclosure includes a photodiode element 102 having an improved geometrical pattern or array of detectors. The array combines a center quadrant (or segmented PSD) with radial wedges (a 1D PSD) that extend outward from the center quadrant to the periphery of the photodiode element 102. Several embodiments of the optical detector system 100 are disclosed.

In certain embodiments, the photodiode elements 102 may be implemented as focal plane arrays (FPAs) A FPA is an arrangement of multiple photodiode element elements, typically organized in a one-dimensional (linear) or two-dimensional (matrix) configuration, that are positioned at the focal plane of an optical system. This configuration enables the simultaneous detection of light at multiple spatial locations, thereby facilitating the acquisition of spatially resolved optical information across the detector surface. The use of FPAs as photodiode elements 102 can be particularly advantageous in applications requiring high spatial resolution or parallel detection of optical signals.

Such FPA photodiode elements 102 may comprise a plurality of individual photodiode elements, each capable of generating an electrical signal in response to incident light. These photodiode elements can be fabricated using semiconductor processes similar to those used for single-element photodiodes but arranged in a regular grid or linear array to form the FPA. The electrical signals from each element of the array can be read out individually or in groups, depending on the desired imaging or detection modality.

In certain embodiments, the focal plane array may be configured as a one-dimensional linear array, suitable for line-scanning applications or for detecting the position of a light beam along a single axis. Alternatively, the FPA may be a two-dimensional matrix, enabling full-field imaging or the detection of complex spatial light patterns. The choice between linear and matrix configurations may be determined by the specific requirements of the optical system and the nature of the signals to be detected.

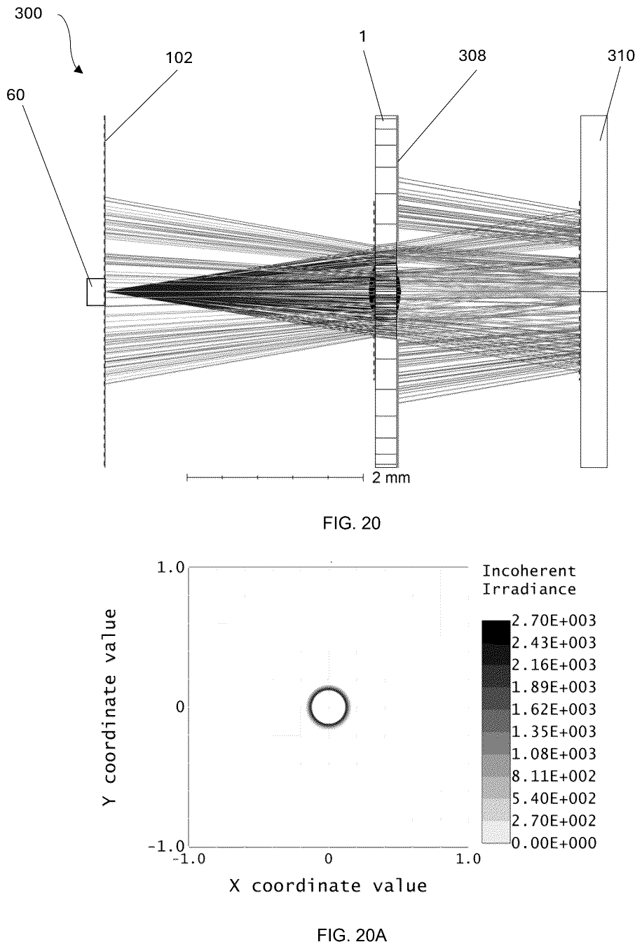

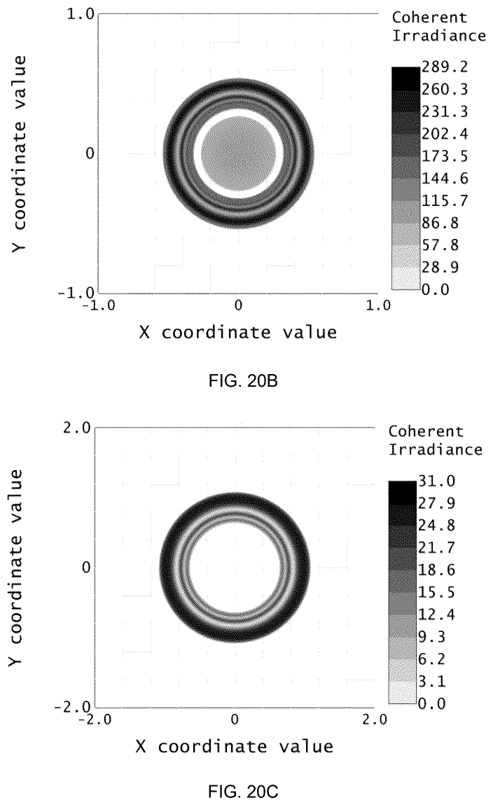

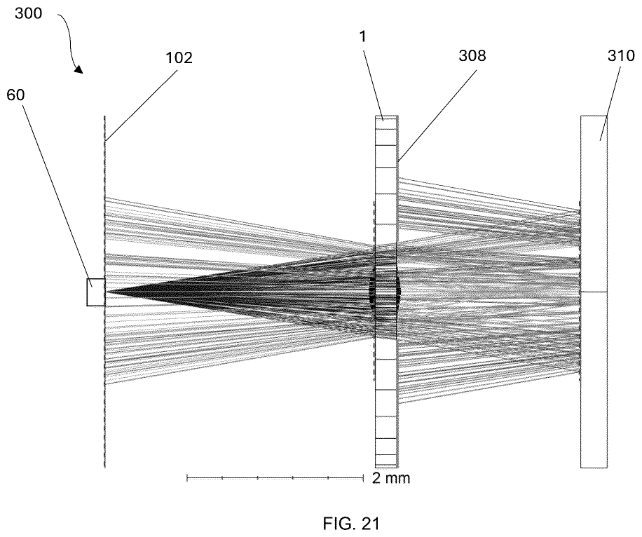

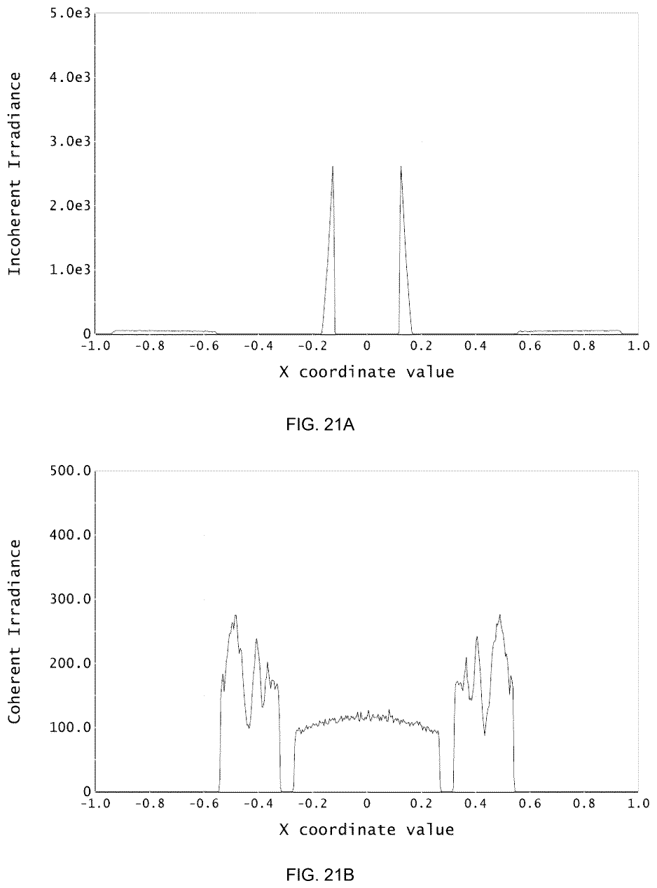

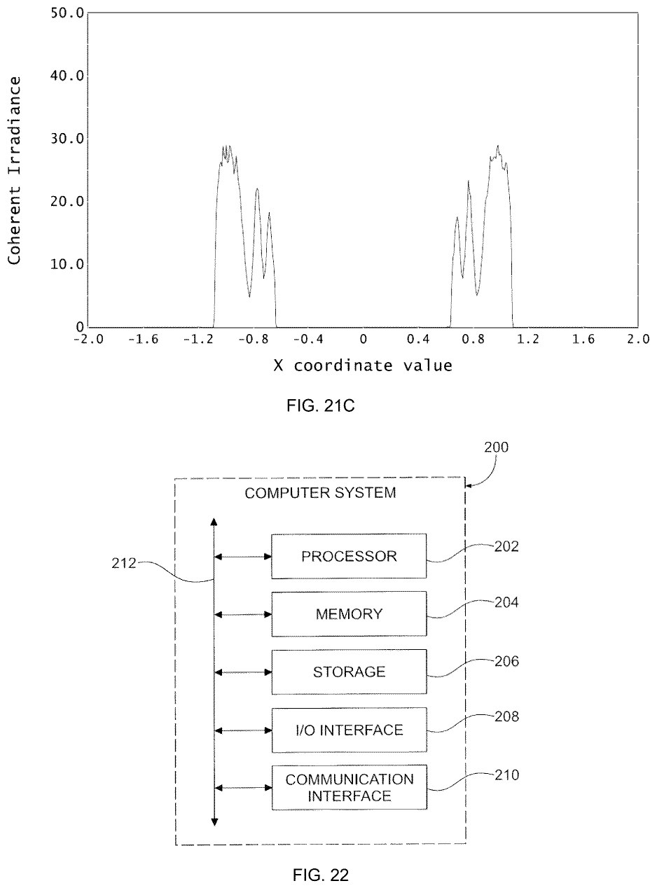

The integration of photodiode element FPAs as element 102 allows for enhanced functionality, such as the ability to perform spatially resolved measurements of irradiance, as shown in the detector images of FIGS. 20 and 21. These figures illustrate the spatial distribution of coherent and incoherent irradiance across the detector surface, which can be captured and analyzed using an FPA. The use of an FPA enables the system to capture detailed spatial profiles of the incident light, which may be useful for beam profiling, wavefront sensing, or other advanced optical measurements.

Focal plane arrays used as photodiode elements 102 may be fabricated from various semiconductor materials, such as silicon, indium gallium arsenide, or other materials suitable for the desired wavelength range. The array may include integrated readout circuitry, such as multiplexers or amplifiers, to facilitate the efficient extraction and processing of signals from the individual detector elements. In some embodiments, the FPA may be cooled or otherwise optimized to reduce noise and enhance sensitivity, depending on the application requirements.

The use of FPAs as photodiode elements 102 also enables advanced signal processing techniques, such as pixel binning, region-of-interest selection, or real-time image analysis. These capabilities can be leveraged to improve the signal-to-noise ratio, increase dynamic range, or enable adaptive measurement strategies. The system may further include a processor or computer system, such as that illustrated in FIG. 22, to manage the acquisition, processing, and analysis of data from the FPA.

Such embodiments where photodiode elements 102 comprise FPAs provide a flexible and robust platform for capturing spatially resolved optical data, supporting a wide range of measurement and imaging applications. The versatility of FPAs allows the system to be readily adapted to different optical configurations and detection requirements, whether for high-resolution imaging, beam profiling, or other advanced optical analyses. This adaptability ensures that the photodiode element arrangement can be optimized for the specific needs of the system, while maintaining compatibility with the other components and functionalities described herein.

As illustrated in FIG. 9, the center quadrant of the photodiode element 102 may have four, discrete and independent inner quadrant sections 110 each separated by a gap 112. Each quadrant section 110 has an individual anode 114 associated with it. A separate lead 116 connects the anode 114 of each of the four quadrant sections 110 to a corresponding anode bond pad 118 located at the perimeter of the photodiode element 102. Although four inner quadrant sections 110 are illustrated in the embodiment shown in FIG. 9, the number of inner quadrant sections 110 may be varied (to, for example, three or more) or decreased (to, for example, two) depending upon the application and specified performance requirements.

As also illustrated in FIG. 9, the radial wedges of the photodiode element 102 may include twenty-four, discrete and independent radial wedge sections 120 each separated by a gap 122. Each radial wedge section 120 has an individual anode 124 associated with it. A separate lead 126 connects the anode 124 of each of the radial wedge sections 120 to a corresponding anode bond pad 128 located at the perimeter of the photodiode element 102. Each radial wedge section 120 has a pie shape with a narrower head proximate the center of the photodiode element 102 and a wider foot proximate the periphery of the photodiode element 102. In the example illustrated, each radial wedge section 120 has an inner diameter of about 1.16 mm and an outer diameter of about 4.4 mm, and extends at an angle of about 14 degrees. Although twenty-four radial wedge sections 120 are illustrated in the embodiment shown in FIG. 9, the number of radial wedge sections 120 may be increased (to, for example, twenty-eight, thirty-two, thirty-six, or more) or decreased (to, for example, twenty, sixteen, twelve, or less) depending upon the application and specified performance requirements. A circular opening 130 separates the inner quadrant sections 110 from the radial wedge sections 120.

The width, length, and number of the individual radial wedge sections 120 can be optimized to accommodate a small spot beam so that there is no positional ambiguity. Therefore, the photodiode element 102 of the optical detector system 100 avoids the ambiguity found in existing position sensing detectors when small beam diameters are used. Further, the radial wedge sections 120 can be electrically configured to provide both a radial distance and an angular position to vastly improve guidance when the optical detector system 100 is used for beam steering. The optical detector system 100 can support a simple optical window or specific lensing can be used to manipulate an incoming beam into a unique output so as to fall onto the radial wedge sections 120 or the inner quadrant sections 110 to provide a unique photoelectric displacement output. The optical detector system 100 can also minimize the size of the center of the array, without sacrificing wide-field accuracy, and can better accommodate blind spots.

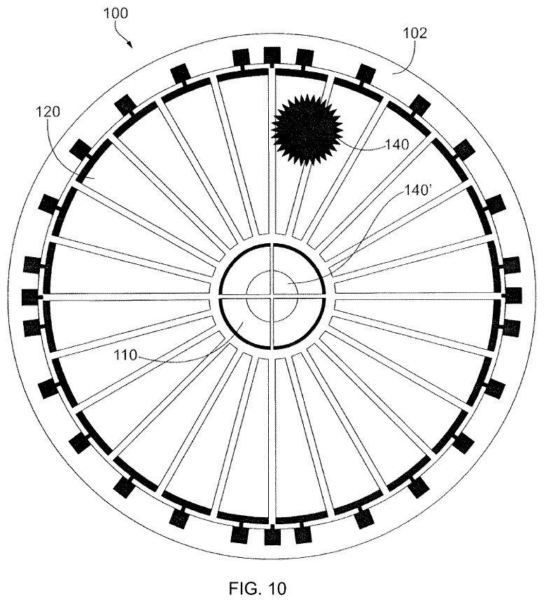

FIG. 10 depicts the optical detector system 100 illustrated in FIG. 9 with a light beam impinging on the photodiode element 102 to create a spot 140. Typically, the light beam emanates from a laser. A laser is a device that emits light through a process of optical amplification based on the stimulated emission of electromagnetic radiation. The word “laser” originated as an acronym for “light amplification by stimulated emission of radiation.” A laser differs from other sources of light in that it emits light that is coherent. Spatial coherence allows a laser to be focused to a tight spot. Spatial coherence also allows a laser beam to stay narrow over great distances (collimation).

The goal of the optical detector system 100 is to position the spot 140 precisely at the center of the photodiode element 102 (where the spot 140′ is shown in FIG. 10). The recommended diameter of the spot 140 is between about 50% and 75% of the diameter of the inner quadrant sections 110. Small spots 140, not spanning more than one detector 110, 120, become “ambiguous” within that detector, losing spatial resolution until either (a) the size of the spot 140 increases to encompass more than one detector, or (b) the spot 140 moves. The radial wedge sections 120 offer position resolution only to the limit of indicating that the spot 140 is within a particular radial wedge section 120 and not where the spot 140 is located within that radial wedge section 120. If the dimensions of the photodiode element 102 are predetermined with respect to the size of the spot 140, then when the spot 140 is in one of the radial wedge sections 120, the centering direction can easily be determined because the spot 140 would cover at least two radial wedge sections 120. By “predetermined” is meant determined beforehand, so that the predetermined characteristic must be determined, i.e., chosen or at least known, before construction of the optical detector system 100.

The embodiment of the optical detector system 100 illustrated in FIGS. 9 and 10 has one, single anode contact per detector (i.e., per inner quadrant section 110 and per radial wedge section 120). Therefore, position sensing is dependent upon the detector only. The photodiode element 102 of the optical detector system 100 has a single shared and common cathode. The cathode is located on the side of the photodiode element 102 opposite the anodes 114, 124 and preferably extends entirely along that side.

The optical detector system 100 requires flip chip for connectivity (i) between the four quadrant sections 110 and their corresponding anode bond pads 118; and (ii) between the radial wedge sections 120 and their corresponding anode bond pads 128. Therefore, the optical detector system 100 is preferably back-side illuminated. Flip chip, also known as controlled collapse chip connection or its abbreviation, C4, is a method for interconnecting dies such as semiconductor devices, integrated circuit chips, integrated passive devices, and microelectromechanical systems (MEMS), to external circuitry with solder bumps that have been deposited onto the chip pads. The solder bumps are deposited on the chip pads on the top side of the wafer during the final wafer processing step. In order to mount the chip to external circuitry (e.g., a circuit board or another chip or wafer), it is flipped over so that its top side faces down, and aligned so that its pads align with matching pads on the external circuit, and then the solder is reflowed to complete the interconnect. The flip chip connectivity is in contrast to wire bonding, in which the chip is mounted upright and fine wires are welded onto the chip pads and lead frame contacts to interconnect the chip pads to external circuitry.

A back-illuminated sensor, also known as a backside illumination (BI) sensor, is a type of digital image sensor that uses a novel arrangement of the imaging elements to increase the amount of light captured and thereby improve low-light performance. A traditional, front-illuminated sensor is constructed in a fashion similar to the human eye, with a lens at the front and photodiode elements at the back. This traditional orientation of the sensor places the active matrix of the sensor—a matrix of individual picture elements—on its front surface and simplifies manufacturing. The matrix and its wiring reflect some of the light, however, and thus the photocathode layer can only receive the remainder of the incoming light; the reflection reduces the signal that is available to be captured.

A back-illuminated sensor contains the same elements as the front-illuminated sensor, but arranges the wiring behind the photocathode layer by flipping the silicon wafer during manufacturing and then thinning its reverse side so that light can strike the photocathode layer without passing through the wiring layer. This change can improve the chance of an input photon being captured from about 60% to over 90%. The greatest difference is realized when pixel size is small, because the light capture area gained in moving the wiring from the top (light incident) to bottom surface is proportionately smaller for a larger pixel.

The embodiment of the optical detector system 100 illustrated in FIGS. 9 and 10 offers excellent performance for relatively large spots 140 where position accuracy is required. It works well for both Gaussian and top-hat beams. In optics, a Gaussian beam is a beam of electromagnetic radiation with high monochromaticity whose amplitude envelope in the transverse plane is given by a Gaussian function; this also implies a Gaussian intensity (irradiance) profile. This fundamental transverse Gaussian mode describes the intended output of most (but not all) lasers, as such a beam can be focused into the most concentrated spot. A flat-top beam (or top-hat beam) is a light beam (often a transformed laser beam) having an intensity profile which is flat over most of the covered area. This is in contrast to Gaussian beams, where the intensity smoothly decays from its maximum on the beam axis to zero.

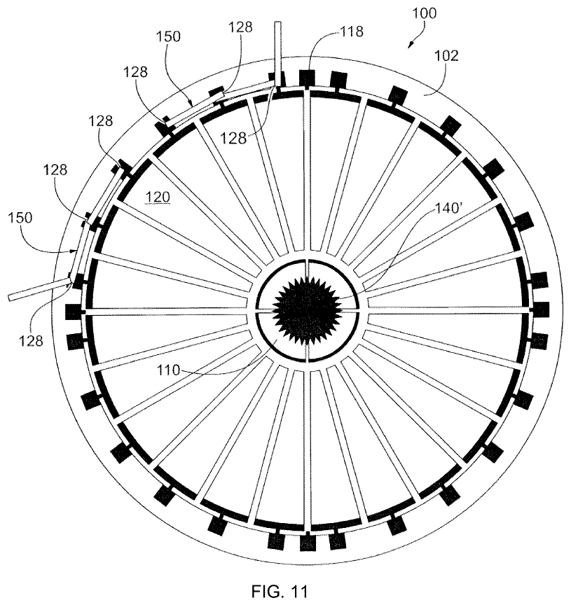

FIG. 11 illustrates another embodiment of the optical detector system 100 that includes one or more shorting links 150. Each radial wedge section 120 can be individually addressed or permanently configured (during manufacture of the optical detector system 100) with one or more shorting links 150. The shorting links 150 reduce the number of pie-shaped radial wedge sections 120 downward to, ultimately, one continuous outer ring. An advantage of reducing the number of radial wedge sections 120 is that the number of outputs, which need to be processed, is also reduced.

Another variation in the embodiment of the optical detector system 100 illustrated in FIGS. 9 and 10 seeks to lower the capacitance of the detectors in the radial wedge section 120. This goal is achieved by reducing the detector area in each of the radial wedge sections 120. Several design variations reduce the detector area, including a contiguous photodiode element structure and an island photodiode element structure in which the islands are wire bonded together (e.g., using shorting links 150 such as those illustrated in FIG. 11) to form a parallel capacitive network in each of the radial wedge sections 120.

More specifically, the number and/or geometry of each of the radial wedge sections 120 can be reduced to reduce the detector area. Rather than twenty-four discrete and independent radial wedge sections 120 each separated by a gap 122, there may be only twelve discrete and independent radial wedge sections 120 each separated by a larger gap 122. Rather than having a pie shape, each radial wedge section 120 may have a substantially rectangular shape separated from adjacent radial wedge sections 120 by gaps 122 that have both a relatively large area and a substantially rectangular shape themselves. Each radial wedge section 120 may have a diamond shape. Each radial wedge section 120 may be configured as a sparse or relatively thin line detector. Although the radial wedge sections 120 may have a pie shape, the sections may not extend from a narrower head proximate the center of the photodiode element to a wider foot proximate the periphery of the photodiode element, i.e., the radial wedge sections 120 may extend instead from a narrower head somewhat removed from the center of the photodiode element and a wider foot proximate the periphery of the photodiode element. Similarly, other shapes (e.g., diamond and line) may not extend fully from the center to the periphery of the photodiode element.

The result of wire bonding the design variations outlined above for reducing the detector area in each of the radial wedge sections 120 would be that the parallel capacitance in the outer quadrant sections 120 can be made greater than (e.g., pie-shaped detectors), less than (e.g., thin line detectors), or equal to (e.g., diamond-shaped detectors) the capacitance of the inner quadrant sections 110 depending on application requirements.

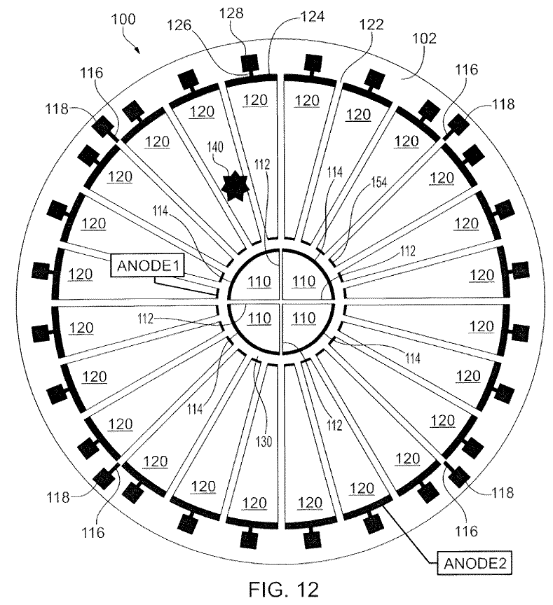

FIG. 12 illustrates yet another embodiment of the optical detector system 100 that includes two anode contacts per detector in the radial wedge section of the array of detectors. The embodiment illustrated in FIG. 12 has all of the components of the embodiment illustrated in FIGS. 9 and 10. In addition to the anode 124 associated with each radial wedge section 120, however, each radial wedge section 120 of the optical detector system 100 illustrated in FIG. 12 has a second anode 154. The second anode 154 is an inner anode (closer to the center of the photodiode element 102) labeled “Anode 1” in FIG. 12; the anode 124 is an outer anode (closer to the periphery of the photodiode element 102) labeled “Anode 2” in FIG. 12. Thus, each radial wedge section 120 has two anode contacts.

The embodiment of the optical detector system 100 illustrated in FIG. 12 has one, single anode contact per detector for the inner quadrant sections 110 and two anode contacts per detector for the radial wedge sections 120. The center quadrant performs as a traditional segmented PSD, losing fine resolution if the spot 140 is fully within any single detector. Position sensing in the radial wedge sections 120 is provided by utilizing the known “lateral effect” to provide for 1D position sensing along the radial length of each detector. Such functionality allows a small spot 140 to provide additional spatial data relative to a single-contact detector. Lateral effect photodiodes sense the position of the spot 140 by measuring the change of current between the opposite anodes 124, 154 and the common cathode. They either require a bias current or the current is photogenerated. In either case, their linearity is affected by the non-uniformity of the current distribution between the anodes 124, 154.

More generally, lateral effect sensors use a detector longitudinally to share charge in a ratio of geometric proportion consistent with the gradient of electrical-resistivity uniformity and/or geometric shape. A photon may fall between the two anodes, resulting in a shared charge. The sheet resistance between a spot at location “x” causes charge to flow to the contact of least resistance. With a flux of photons, a statistical probability based upon diffusion conditions causes the ratio of charge collected at one anode to be directly proportional to the distance between the two anodes. For sensors where the resistivity is non-uniform (gradient), or the geometry is not linear (as in a wedge or pie-shape), this must be taken into account, but can be measured by transmission line measurement test structures or modeled with accurate coefficients for material and electrical properties and geometric dimensions.

Like the embodiment of the optical detector system 100 illustrated in FIGS. 9 and 10, the embodiment illustrated in FIG. 12 has a single shared and common cathode, requires flip chip for connectivity, and is preferably back-side illuminated. The embodiment of the optical detector system 100 illustrated in FIG. 12 offers excellent performance for relatively large and small spots 140 where position accuracy is required. High resolution is achieved, which means 1 part in 100 position accuracy or better. Each embodiment works well for both Gaussian and top-hat beams.

The photodiode element 102 in each embodiment of the optical detector system 100 provides an output signal that is indicative of light incident upon its active area. For example, light incident on an active portion of a photodiode element may produce an output current that is proportionate to the power of the incident light. As disclosed above, the individual inner quadrant sections 110 of the photodiode element 102 are separated from one another by a gap 112 and the individual radial wedge sections 120 of the photodiode element 102 are separated from one another by a gap 122. The gap 112, 122 may have a width of about 1 μm, about 10 μm, about 20 μm, about 30 μm, about 40 μm, about 50 μm, about 100 μm, about 1,000 μm (1 mm), or in the range between 1 and 1,000 μm, between 10 and 100 μm, between 20 and 50 μm, between 20 and 40 μm, between 20 and 30 μm, between 30 and 50 μm, or between 40 and 50 μm. The output signals may be processed by a computer apparatus that includes a processor, database, and stored instructions to configure the processor to process data in accordance with the methods of the disclosure.

### B. The VCSEL

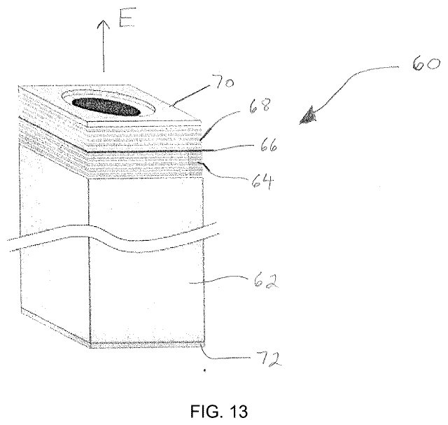

FIG. 13 is a diagram of a simple structure illustrating a vertical-cavity surface-emitting laser (VCSEL) 60 as one suitable example of a light source. The VCSEL 60 is a type of semiconductor laser diode with its laser beam emission E perpendicular from the top surface, contrary to conventional edge-emitting semiconductor lasers (also in-plane lasers) which emit from surfaces formed by cleaving the individual chip out of a wafer. The structure begins with an n-type semiconductor substrate 62, usually composed of materials like gallium arsenide (GaAs) or indium phosphide (InP), providing a solid foundation. Just above the substrate is positioned a lower distributed Bragg reflector (DBR) 64. The lower DBR 64 consists of multiple alternating layers of semiconductor materials with different refractive indices, designed to reflect light strongly at specific wavelengths. Situated above the lower DBR 64 is an active region 66 or gain structure. The active region 66 typically contains ultra-thin layers known as quantum wells, each measuring only a few nanometers thick. The laser light is efficiently generated through the recombination of electrons and holes in the quantum wells.

Surrounding the active region 66 are additional layers, often acting as electrical conductors, that facilitate current injection and serve as an upper DBR 68. Like its bottom counterpart, the upper DBR 68 ensures that emitted light remains within the cavity, contributing to the high efficiency and precise wavelength control of the laser. Thus, the laser resonator consists of two DBR mirrors 64, 68 parallel to the wafer surface with the active region 66 in between. The planar DBR mirrors 64, 68 consist of layers with alternating high and low refractive indices. Each layer has a thickness of a quarter of the laser wavelength in the material, yielding intensity reflectivities above 99%. High reflectivity mirrors are required in VCSELs to balance the short axial length of the gain region.

In common VCSELs the upper and lower mirrors 64, 68 are doped as p-type and n-type materials, forming a diode junction. In more complex structures, the p-type and n-type regions may be embedded between the mirrors 64, 68, requiring a more complex semiconductor process to make electrical contact to the active region 66, but eliminating electrical power loss in the DBR structure.

VCSELs function by injecting an electrical current into the semiconductor structure through an upper metal contact 70 and a lower metal contact 72. This current causes electrons and holes to recombine within the active region 66 of the semiconductor, releasing photons in the process. These photons are confined within the laser cavity, formed by the highly reflective DBRs 64, 68, where they undergo resonance and intensity amplification. As a result, coherent laser light is emitted perpendicular to the surface through the upper DBR 68. The power of the emitted light can be controlled by adjusting the injected current.

VCSELs for wavelengths from 650 nm to 1300 nm are typically based on gallium arsenide (GaAs) wafers with DBRs formed from GaAs and aluminum gallium arsenide (AlₓGa₍₁₋ₓ₎As). The GaAs—AlGaAs system is favored for constructing VCSELs because the lattice constant of the material does not vary strongly as the composition is changed, permitting multiple “lattice-matched” epitaxial layers to be grown on a GaAs substrate. The refractive index of AlGaAs does vary relatively strongly as the Al fraction is increased, however, minimizing the number of layers required to form an efficient Bragg mirror compared to other candidate material systems. Furthermore, at high aluminum concentrations, an oxide can be formed from AlGaAs, and this oxide can be used to restrict the current in a VCSEL, enabling very low threshold currents.

The larger output aperture of VCSELs, compared to most edge-emitting lasers, produces a lower divergence angle of the output beam. The small active region, compared to edge-emitting lasers, reduces the threshold current of VCSELs, resulting in low power consumption. The low threshold current also permits high intrinsic modulation bandwidths in VCSELs. The wavelength of VCSELs may be tuned, within the gain band of the active region, by adjusting the thickness of the reflector layers.

VCSELs are known for their high power conversion efficiency, leading to less energy waste and lower operating costs. They produce a circular, low divergence beam which simplifies coupling to optical fibers and facilitates array formation. VCSELs can modulate directly at very high frequencies, often exceeding several tens of GHz. VCSELs can be tested and characterized on-wafer before they are cleaved into individual chips, reducing production costs. A suitable VCSEL 60 is commercially available as Model V00140 from Vixar Inc. of Plymouth, Minnesota.

As an alternative to the VCSEL 60, the light source may be a microelectromechanical system (MEMS) tunable VCSEL. A MEMS tunable VCSEL is a compact, high-speed laser light source whose wavelength is tunable over a wide range. The operating principle of a silicon-MEMS tunable VCSEL is as follows: when a voltage is applied to the upper and lower layers of the Si-MEMS substrate, static electricity occurs and attracts a thin film of silicon on the upper layer toward the lower layer. As a result, the optical resonator becomes longer and the laser oscillation wavelength increases accordingly. With this mechanism, wavelengths can be swept continuously, which is particularly useful for optical measurements.

MEMS tunable VCSELs are commercially available, for example, from Thorlabs, Inc. of Newton, New Jersey and Yokogawa Corporation of America of Houston, Texas. A tunable wavelength laser such as a MEMs tunable VCSEL enables the sensor to measure semi-transparent material via a variation in optical coherent tomography (OCT) systems requiring superior sensitivity. The MEMs tunable VCSEL may include an active power control that maintains constant output power over the lifetime of the laser.

### C. The Interferometer

The principles of interference are easy to understand and begin when two or more light waves interact. Add the heights and depths of the separate waves where they interact, and the result is the interference pattern. Two specific kinds of interference define a spectrum of possibilities. Total constructive interference happens when the peaks and troughs of identical waves perfectly coincide. The result is a larger wave equal in size to the sum of the heights (and depths) of the merging waves at each point where they intersect (i.e., the brightness of the resulting beam is the sum of brightnesses of the interacting beams). Total destructive interference is the exact opposite. When the peaks of one wave meet and exactly match the troughs of identical waves, they cancel each other out and no wave results (i.e., there is no light). Of course, in nature, two or more light waves are rarely identical, and the peaks and troughs of one wave will rarely perfectly meet the peaks or troughs of another wave. Regardless, no matter how they differ, when the waves intersect, the result is always the sum of the heights and depths of the waves wherever they intersect. This means that the alignment of the waves as they interact dictates the resulting interference pattern.

Interferometers are investigative tools used in many fields of science and engineering. Pioneered in the mid- to late-1800s, they are called interferometers because they work by merging sources of light to create an interference pattern, which can be measured and analyzed: hence “interfere-meter” or interferometer. The interference patterns generated by interferometers contain information about the object being studied. They are often used to make very small measurements that cannot be achieved any other way. Despite their different designs and the various ways in which they are used, all interferometers have one thing in common: they superimpose beams of light to generate an interference pattern.

The Michelson interferometer is a common configuration for optical interferometry and was invented by the 19/20th-century American physicist Albert Abraham Michelson. Using a beamsplitter, a light source is split into two beams. Each of those light beams is reflected back toward the beamsplitter which then combines their amplitudes using the superposition principle. The resulting interference pattern that is not directed back toward the source is typically directed to some type of photoelectric detector or camera that records the interference pattern. For different applications of the interferometer, the two light paths can have different lengths or incorporate optical elements or even materials under test.

The Mach-Zehnder interferometer is a device used to determine the relative phase shift variations between two collimated beams derived by splitting light from a single source. The interferometer has been used, among other things, to measure phase shifts between the two beams caused by a sample or a change in length of one of the paths. The apparatus is named after the physicists Ludwig Mach (the son of Ernst Mach) and Ludwig Zehnder; Zehnder's proposal in an 1891 article was refined by Mach in an 1892 article. Mach-Zehnder interferometry with electrons as well as with light has been demonstrated. The versatility of the Mach-Zehnder configuration has led to its being used in a range of research efforts especially in fundamental quantum mechanics. The Mach-Zehnder check interferometer is a highly configurable instrument. In contrast to the well-known Michelson interferometer, each of the well-separated light paths is traversed only once.

A Mirau interferometer works on the same basic principle as a Michelson interferometer. The difference between the two is in the physical location of the reference beam. The reference arm of a Mirau interferometer is located within a microscope objective assembly. It is named after André Henri Mirau, who obtained U.S. Pat. No. 2,612,074 on the concept in 1952.

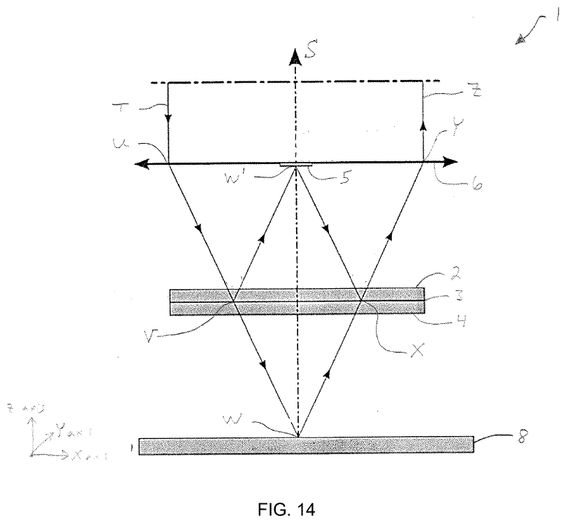

A schematic of a Mirau interferometer 1 is shown in FIG. 14. The Mirau interferometer 1 receives a light beam T from a source S, divides the light beam T into two portions having substantially equal optical paths which create interferences, and directs some of that light toward and onto the surface of a sample or object 8. The Mirau interferometer 1 includes a separator or beam splitter which has at least one semi-transparent thin layer 3 disposed between two transparent plates 2, 4. The incident light beam T initially passes through a lens 6 at a point U, which directs the beam toward the beam splitter 2, 3, 4. A reflector or reference mirror 5 is positioned on the lens 6 facing the beam splitter 2, 3, 4. At point V of the thin layer 3, the source light is split into (i) a reference beam which reflects off the thin layer 3 and travels a reference path toward the mirror 5 where the reference beam reflects off the mirror 5 at a point W′, and contacts the thin layer 3 of the beam splitter 2, 3, 4 at a point X; and (ii) an object beam which travels an object path as the reference beam reflects off the object 8 at a point W and contacts the thin layer 3 of the beam splitter 2, 3, 4 at the point X. The reference and object paths recombine at the point X to form an interference image. FIG. 14 shows the optical paths of the Mirau interferometer 1. The reference beam (V-W′-X) and the object beam (V-W-X) have an identical optical path length and can thus cause white light interference.

More generally, the incident light beam T travels two paths. The first path TUVWXYZ passes through the lens 6 then through the beam splitter 2, 3, 4, reflects off the object 8, passes back through the beam splitter 2, 3, 4 then through the lens 6 (at the point Y), and returns as part of the beam Z to the objective or viewing device. The incident light beam T also travels a second path TUVW′XYZ with successive reflections off the beam splitter 2, 3, 4 and the mirror 5 before returning to the viewing device as part of the beam Z.

A Cartesian coordinate system (x, y, z) is a coordinate system that specifies each point uniquely in three-dimensional space by three Cartesian numerical coordinates, which are the signed distances to the point from three, fixed, mutually perpendicular directed lines, measured in the same unit of length. Each reference line is called a coordinate axis or just an axis of the system, and the point where they meet is its origin, usually at ordered triplet (0, 0, 0). The coordinates can also be defined as the positions of the perpendicular projections of the point onto the three axes, expressed as signed distances from the origin. The coordinate measured from the y-axis parallel to the x-axis is called the abscissa and the other coordinate in the x-y plane is called the ordinate. The z-axis extends vertically from the horizontal x-y plane. The coordinate system is illustrated in FIG. 14.

By changing the z position of the object 8, interference images are acquired at a sequence of path (phase) differences: 0, λ/4, λ/2, and 3λ/4. These interference maps are functions of background intensity, fringe modulation, and phase. Three such images provide enough information to solve for the topographic image of the object 8. The Mirau interferometer 1 also makes it possible to determine, with a high precision and without contacting the object 8, the relative position of the object 8.

### D. The Optoelectronic Package

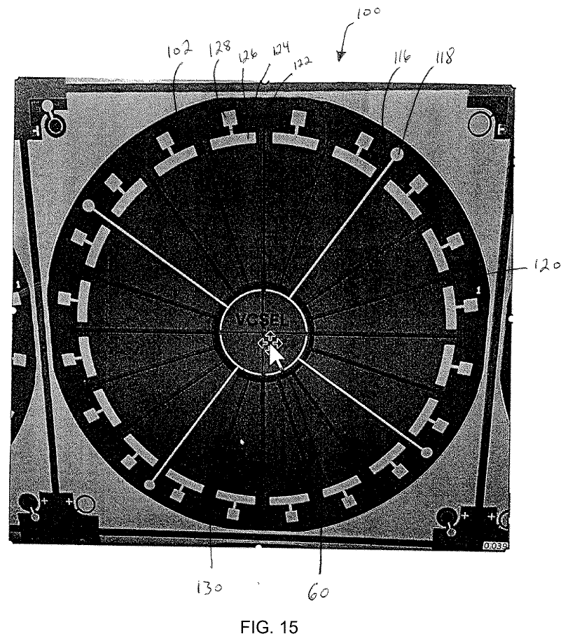

FIG. 15 illustrates one example embodiment of the optical detector system 100 including the photodiode element 102 having the VCSEL 60 instead of the inner quadrant sections 110. Thus, the optical detector system 100 of FIG. 15 does not have four discrete and independent inner quadrant sections 110 each separated by a gap 112; an individual anode 114 associated with each quadrant section 110; or a separate lead 116 connecting the anode 114 of each of the four quadrant sections 110 to a corresponding anode bond pad 118 located at the perimeter of the photodiode element 102. Other than replacing the inner quadrant sections 110 at the center of the optical detector system 100 with the VCSEL 60, however, the optical detector system 100 of FIG. 15 is substantially similar to the optical detector system 100 of FIG. 9. Specifically, the optical detector system 100 of FIG. 15 has radial wedge sections 120.

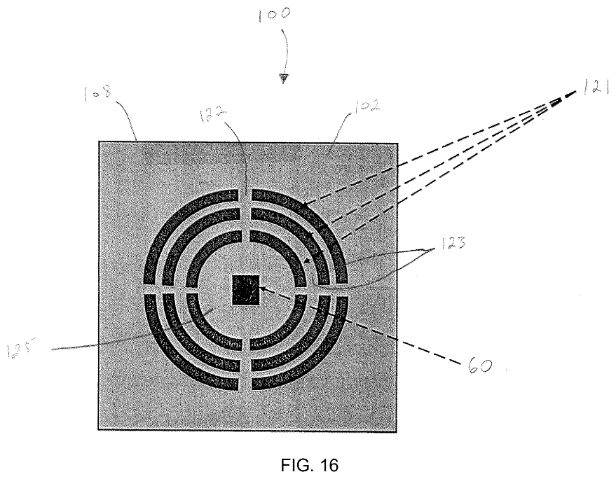

FIG. 16 illustrates another example embodiment of the optical detector system 100 including the photodiode element 102 having the VCSEL 60. The photodiode element 102 is placed on a semiconductor chip 108, and the chip of the VCSEL 60 is attached to the chip 108. In this embodiment, the photodiode element 102 has concentric arc sections 121 rather than the radial wedge sections 120 of earlier embodiments. The concentric arc sections 121 are separated from each other by open, concentric rings 123. The concentric arc sections 121 are separated into four quadrants by the gaps 122.

As also illustrated in FIG. 16, the concentric arc sections 121 of the photodiode element 102 include twelve discrete and independent concentric arc sections 121 each separated by the gaps 122 and the rings 123. Although not shown, each concentric arc section 121 has an individual anode associated with it. A separate lead connects the anode of each of the concentric arc sections 121 to a corresponding anode bond pad located at the perimeter of the photodiode element 102. Although twelve concentric arc sections 121 are illustrated in the embodiment shown in FIG. 16, the number of concentric arc sections 121 may be increased (to, for example, sixteen, twenty, twenty-four, or more) or decreased (to, for example, eight or less) depending upon the application and specified performance requirements. A circular opening 125 separates the VCSEL 60 from the concentric arc sections 121. The VCSEL 60 shown in FIG. 16 may produce a laser having a wavelength, for example, of about 895 nm.

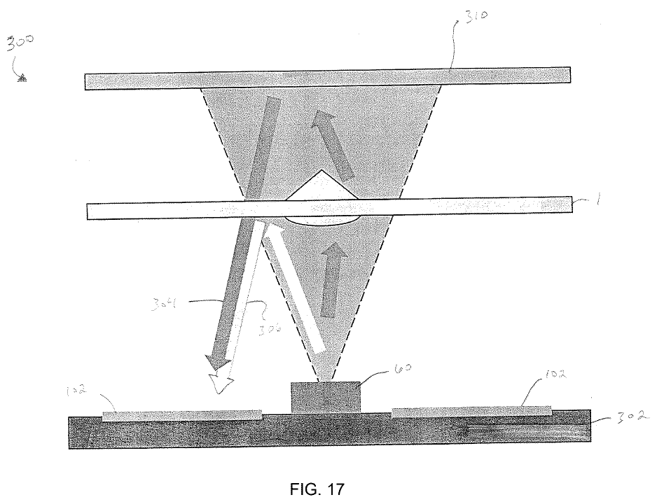

The photodiode element 102 shown in FIG. 16 is preferred for use in an optoelectronic package 300. An embodiment of the optoelectronic package 300 is shown in FIG. 17. The optoelectronic package 300 includes a leadless chip carrier (LCC) 302. An LCC is a type of integrated circuit (IC) package that has no pins or leads for contact. Instead, the LCC uses metal pads at the outer edges to establish direct connection with the printed circuit board (PCB) thus reducing the overall footprint of the package. LCCs have gained significant traction in electronics manufacturing due to their compact size, improved thermal performance, and enhanced electrical characteristics. LCCs not only allow for higher component density on PCBs but also facilitate automated assembly processes, leading to improved manufacturing efficiency and cost-effectiveness. In addition, the absence of leads minimizes the risk of signal distortion and electromagnetic interference (EMI), resulting in enhanced signal integrity and reliability. Overall, LCCs represent a significant advancement in IC packaging technology, offering a compelling solution for modern electronics design and manufacturing needs.

On the LCC 302 is positioned the photodiode element 102 including the VCSEL 60 as illustrated in FIG. 16. Thus, the photodiode element 102 including the VCSEL 60 forms part of the optoelectronic package 300 as shown in FIG. 17. The Mirau interferometer 1 as illustrated in FIG. 14 is positioned between the VCSEL 60 and the object 310, such as a semiconductor wafer. Thus, the Mirau interferometer 1 also forms part of the optoelectronic package 300 as shown in FIG. 17. One benefit of the Mirau interferometer 1 is that it produces a series of interference rings rather than the lines produced by other types of interferometers. As the displacement of the object 310 changes, the interference rings produced by the Mirau interferometer 1 also change.

In summary, the optoelectronic package 300 includes the photodiode element 102 having multiple concentric arc sections 121, a laser diode (preferably the VCSEL 60) located centrally within the photodiode element 102, and the interferometer (preferably, the Mirau interferometer 1) and functions to measure the surface of the object 310. As shown in FIG. 17, the optoelectronic package 300 projects a ring of measured light 304 which reflects off the measured surface of the object 310 and combines with a ring of reference light 306 to produce interference fringes on the series of concentric arc sections 121 of the photodiode element 102. Accordingly, the concentric arc sections 121 of the photodiode element 102 will see varying light intensity due to optical interference. The variations in light amplitude will correspond to motion (both displacement and angular tip/tilt) of the measured surface of the object 310 thereby allowing the optoelectronic package 300 to precisely measure normal and angular displacements of the measured surface of the object 310.

Extremely precise measurement of both surface displacement (submicron levels) and angular displacement (microradian levels) is extremely important in many industries, but none more so than semiconductor wafer processing. Traditionally these measurements are very difficult to integrate into wafer processing equipment due to the size and complexity of measurement systems. Further, conventional systems typically offer only a displacement measurement. The optoelectronic package 300 offers a precise measurement with three degrees of freedom (displacement, tip, and tilt) which can be embedded into the extremely small spaces often found in semiconductor wafer processing equipment.

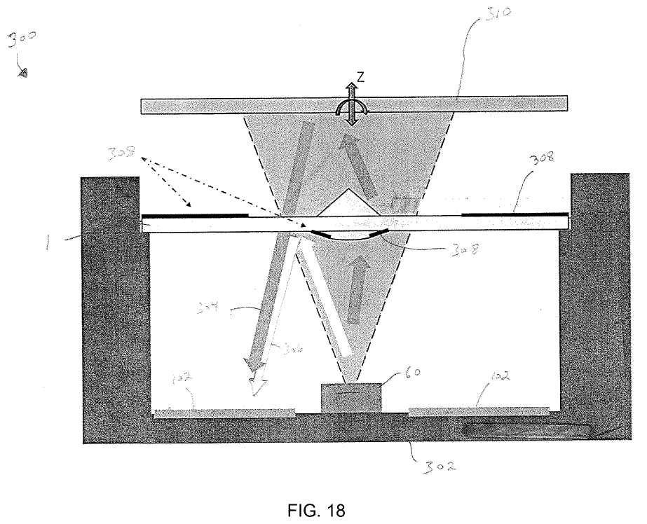

The optoelectronic package 300 may also include a black mask 308 which can be provided in one or more layers as shown in FIG. 18. Certain layers of the black mask 308 are located concentrically on the Mirau interferometer 1 (more specifically, the black mask 308 may be located on various areas of the lens 6, the photodiode element 102, or both components) to absorb or trap light and thereby minimize stray light and its adverse effects. For example, because it is undesirable in the outer portion of the optoelectronic package 300 to have the reflected light return to the photodiode element 102, the black mask 308 blocks such light. Only the center portion of the laser emitted by the VCSEL 60 reaches the photodiode element 102. Therefore, stray light that would produce noise in the interference pattern is eliminated. The anti-reflective (AR) characteristic of the Mirau interferometer 1 may be about 0.025%, about 1%, or in the range between about 0.025% and about 1%.

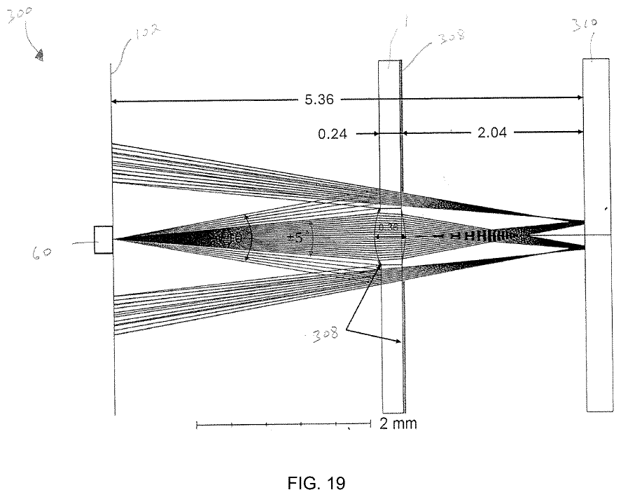

FIG. 19 illustrates a trace of the laser beam rays emitted by an example VCSEL 60 used in the optoelectronic package 300 depicted in FIG. 18. The example VCSEL 60 is preferably made of GaAs and emits a laser beam with a coherence length of about 39.2 mm, a beam radiation angle ratio of about 0.98, and a wavelength (λ) of about 894.6 nm. The outer portion of the divergent cone of light rays (±10°) emitted by the VCSEL 60 forms the reference light 306 that produces interference fringes on the series of concentric arc sections 121 of the photodiode element 102. The inner portion of the divergent cone of light rays (±5°) emitted by the VCSEL 60 forms the measured light 304 that produces interference fringes on the series of concentric arc sections 121 of the photodiode element 102.

Also illustrated in FIG. 19 are some example dimensions for the optoelectronic package 300. The distance from the VCSEL 60 to the measured surface of the wafer (object 308) is about 5.36 mm. The width of the Mirau interferometer 1 is about 0.38 mm at its center and about 0.24 mm at its edges where portions of the black mask 308 exist. The distance from the black mask 308 on the edges of the Mirau interferometer 1 to the measured surface of the wafer (object 308) is about 2.04 mm. Example specifications for the optoelectronic package 300 depicted in FIG. 18 are summarized as follows. The wafer (object 310) z-axis measurement range is about 2 mm; the wafer tip/tilt range is about ±5 degrees; the wafer z-axis resolution is about 100 nm; the wafer tip/tilt resolution is about 2.5 μradians (1.4×10-4 degrees); and the wafer/sensor window standoff is about 5 mm.

FIG. 20 illustrates another trace of the laser beam rays emitted by an example VCSEL 60 used in the optoelectronic package 300 depicted in FIG. 18. FIG. 20A depicts the interference pattern that appears on the measured surface of the wafer (object 308). FIG. 20B depicts the interference pattern that appears on the surface of the Mirau interferometer 1. FIG. 20C depicts the interference pattern that appears on the concentric arc sections 121 of the photodiode element 102. Thus, the concentric arc sections 121 of the photodiode element 102 capture an image of interference fringes created by the Mirau interferometer 1. The coherent irradiance on the surface of the photodiode element 102 shows the concentric fringes. The interference patterns that occur on the concentric arc sections 121 of the photodiode element 102 enable short-range tip/tilt and height measurements of the measured surface of the wafer (object 310).

FIG. 21 simply repeats FIG. 20 and again illustrates another trace of the laser beam rays emitted by an example VCSEL 60 used in the optoelectronic package 300 depicted in FIG. 18. FIG. 21A is a cross section of the interference pattern that appears on the measured surface of the wafer (object 308), showing peaks where the interference rings occur. FIG. 21B is a cross section of the interference pattern that appears on the surface of the Mirau interferometer 1, showing peaks where the interference rings occur. FIG. 21C is a cross section of the interference pattern that appears on the concentric arc sections 121 of the photodiode element 102, showing peaks where the interference rings occur.

### E. The Computer System

FIG. 22 illustrates an example computer system 200 that can be used as part of or in combination with the optoelectronic package 300. In particular embodiments, one or more computer systems 200 engage with one or more components, and perform one or more steps of one or more methods, described or illustrated in this document. In particular embodiments, one or more computer systems 200 provide functionality described or illustrated in this document. In particular embodiments, software running on one or more computer systems 200 performs one or more steps of one or more methods described or illustrated in this document or provides functionality described or illustrated in this document. Particular embodiments include one or more portions of one or more computer systems 200. In this document, reference to a computer system may encompass a computing device, and vice versa, where appropriate. Moreover, reference to a computer system may encompass one or more computer systems, where appropriate.

This disclosure contemplates any suitable number of computer systems 200. This disclosure contemplates the computer system 200 taking any suitable physical form. As example and not by way of limitation, the computer system 200 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these devices. Where appropriate, the computer system 200 may include one or more computer systems 200; be unitary or distributed; span multiple locations; span multiple machines; span multiple data centers; or reside in a cloud, which may include one or more cloud components in one or more networks. Where appropriate, one or more computer systems 200 may perform without substantial spatial or temporal limitation one or more steps of one or more methods described or illustrated in this document. As an example and not by way of limitation, the one or more computer systems 200 may perform in real time or in batch mode one or more steps of one or more methods described or illustrated in this document. The one or more computer systems 200 may perform at different times or at different locations one or more steps of one or more methods described or illustrated in this document, where appropriate.

In particular embodiments, the computer system 200 includes a processor 202, memory 204, storage 206, an input/output (I/O) interface 208, a communication interface 210, and a bus 212. Although this disclosure describes and illustrates a particular computer system having a particular number of particular components in a particular arrangement, this disclosure contemplates any suitable computer system having any suitable number of any suitable components in any suitable arrangement.

In particular embodiments, the processor 202 includes hardware for executing instructions, such as those making up a computer program. As an example and not by way of limitation, to execute instructions, the processor 202 may retrieve (or fetch) the instructions from an internal register, an internal cache, the memory 204, or the storage 206; decode and execute them; and then write one or more results to an internal register, an internal cache, the memory 204, or the storage 206. In particular embodiments, the processor 202 may include one or more internal caches for data, instructions, or addresses. This disclosure contemplates the processor 202 including any suitable number of any suitable internal caches, where appropriate. As an example and not by way of limitation, the processor 202 may include one or more instruction caches, one or more data caches, and one or more translation lookaside buffers (TLBs). Instructions in the instruction caches may be copies of instructions in the memory 204 or the storage 206, and the instruction caches may speed up retrieval of those instructions by the processor 202. Data in the data caches may be copies of data in the memory 204 or the storage 206 for instructions executing at the processor 202 to operate on; the results of previous instructions executed at the processor 202 for access by subsequent instructions executing at the processor 202 or for writing to the memory 204 or the storage 206; or other suitable data. The data caches may speed up read or write operations by the processor 202. The TLBs may speed up virtual-address translation for the processor 202. In particular embodiments, the processor 202 may include one or more internal registers for data, instructions, or addresses. This disclosure contemplates the processor 202 including any suitable number of any suitable internal registers, where appropriate. Where appropriate, the processor 202 may include one or more arithmetic logic units (ALUs); be a multi-core processor; or include one or more processors 202. Although this disclosure describes and illustrates a particular processor, this disclosure contemplates any suitable processor.

In particular embodiments, the memory 204 includes main memory for storing instructions for the processor 202 to execute or data for the processor 202 to operate on. As an example and not by way of limitation, the computer system 200 may load instructions from the storage 206 or another source (such as, for example, another computer system 200) to the memory 204. The processor 202 may then load the instructions from the memory 204 to an internal register or internal cache. To execute the instructions, the processor 202 may retrieve the instructions from the internal register or internal cache and decode them. During or after execution of the instructions, the processor 202 may write one or more results (which may be intermediate or final results) to the internal register or internal cache. The processor 202 may then write one or more of those results to the memory 204. In particular embodiments, the processor 202 executes only instructions in one or more internal registers or internal caches or in the memory 204 (as opposed to the storage 206 or elsewhere) and operates only on data in one or more internal registers or internal caches or in the memory 204 (as opposed to the storage 206 or elsewhere). One or more memory buses (which may each include an address bus and a data bus) may couple the processor 202 to the memory 204. The bus 212 may include one or more memory buses, as described below. In particular embodiments, one or more memory management units (MMUs) reside between the processor 202 and the memory 204 and facilitate accesses to the memory 204 requested by the processor 202. In particular embodiments, the memory 204 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. The memory 204 may include one or more memories 204, where appropriate. Although this disclosure describes and illustrates particular memory, this disclosure contemplates any suitable memory.

In particular embodiments, the storage 206 includes mass storage for data or instructions. As an example and not by way of limitation, the storage 206 may include a hard disk drive (HDD), a floppy disk drive, flash memory, an optical disc, a magneto-optical disc, magnetic tape, or a Universal Serial Bus (USB) drive or a combination of two or more of these. The storage 206 may include removable or non-removable (or fixed) media, where appropriate. The storage 206 may be internal or external to the computer system 200, where appropriate. In particular embodiments, the storage 206 is non-volatile, solid-state memory. In particular embodiments, the storage 206 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates the storage 206 taking any suitable physical form. The storage 206 may include one or more storage control units facilitating communication between the processor 202 and the storage 206, where appropriate. Where appropriate, the storage 206 may include one or more storages 206. Although this disclosure describes and illustrates particular storage, this disclosure contemplates any suitable storage.

In particular embodiments, the I/O interface 208 includes hardware, software, or both, providing one or more interfaces for communication between the computer system 200 and one or more I/O devices. The computer system 200 may include one or more of these I/O devices, where appropriate. One or more of these I/O devices may enable communication between a person and the computer system 200. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 208 for them. Where appropriate, the I/O interface 208 may include one or more device or software drivers enabling the processor 202 to drive one or more of these I/O devices. The I/O interface 208 may include one or more I/O interfaces 208, where appropriate. Although this disclosure describes and illustrates a particular I/O interface, this disclosure contemplates any suitable I/O interface.

In particular embodiments, the communication interface 210 includes hardware, software, or both providing one or more interfaces for communication (such as, for example, packet-based communication) between the computer system 200 and one or more other computer systems 200 or one or more networks. As an example and not by way of limitation, the communication interface 210 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 210 for it. As an example and not by way of limitation, the computer system 200 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, the computer system 200 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. The computer system 200 may include any suitable communication interface 210 for any of these networks, where appropriate. The communication interface 210 may include one or more communication interfaces 210, where appropriate. Although this disclosure describes and illustrates a particular communication interface, this disclosure contemplates any suitable communication interface.

In particular embodiments, the bus 212 includes hardware, software, or both coupling components of the computer system 200 to each other. As an example and not by way of limitation, the bus 212 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. The bus 212 may include one or more buses 212, where appropriate. Although this disclosure describes and illustrates a particular bus, this disclosure contemplates any suitable bus or interconnect.

In this document, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

This disclosure contemplates one or more computer-readable storage media implementing any suitable storage. In particular embodiments, a computer-readable storage medium implements one or more portions of the processor 202 (such as, for example, one or more internal registers or caches), one or more portions of the memory 204, one or more portions of the storage 206, or a combination of these, where appropriate. In particular embodiments, a computer-readable storage medium implements RAM or ROM. In particular embodiments, a computer-readable storage medium implements volatile or persistent memory. In particular embodiments, one or more computer-readable storage media embody software. In this document, reference to software may encompass one or more applications, bytecode, one or more computer programs, one or more executables, one or more instructions, logic, machine code, one or more scripts, or source code, and vice versa, where appropriate. In particular embodiments, software includes one or more application programming interfaces (APIs). This disclosure contemplates any suitable software written or otherwise expressed in any suitable programming language or combination of programming languages. In particular embodiments, software is expressed as source code or object code. In particular embodiments, software is expressed in a higher-level programming language, such as, for example, C, Perl, or a suitable extension thereof. In particular embodiments, software is expressed in a lower-level programming language, such as assembly language (or machine code). In particular embodiments, software is expressed in C++, C#, Python, Java, JavaScript, Solidity, Vyper, Golang, Simplicity, or Rholang. In particular embodiments, software is expressed in Hyper Text Markup Language (HTML), Extensible Markup Language (XML), JavaScript Object Notation (JSON) or other suitable markup language.

Although illustrated and described above with reference to certain specific embodiments and examples, the present disclosure is nevertheless not intended to be limited to the details shown. Rather, various modifications may be made in the details within the scope and range of equivalents of the claims and without departing from the spirit of the disclosure.

What is claimed:

1. An optoelectronic package for measuring the surface of an object, the optoelectronic package comprising:
a carrier;
a segmented ring-patterned photodiode element located on the carrier and having a center opening the photodiode element being adapted to identify varying light intensity based on optical interference;
a vertical-cavity surface-emitting laser (VCSEL) located in the center opening of the photodiode element and directing light rays toward the object; and
a lens positioned between the VCSEL and the object, the lens adapted to receive the light rays from the VCSEL and create a ring of measured light which reflects off the surface of the object and the measured light is adapted to combine with a ring of reference light to produce optical interference on the photodiode element permitting the photodiode element to identify varying light intensity from the optical interference,
wherein variations in light intensity correspond to displacement, angular tip and tilt, or a combination thereof of the surface of the object.

2. The optoelectronic package according to claim 1 further comprising a computer system configured to engage with one or more components of the optoelectronic package.

3. The optoelectronic package according to claim 1 further comprising a thermoelectrically cooled configuration adapted to reduce thermal noise in each photodiode element and remove heat generated by VCSEL.

4. The optoelectronic package according to claim 1 wherein the VCSEL is a microelectromechanical system (MEMS) tunable VCSEL.

5. The optoelectronic package according to claim 1 wherein the photodiode element has multiple concentric arc sections separated into three or more quadrants by gaps and separated from each other by open concentric rings.

6. The optoelectronic package according to claim 1 wherein the object is a motion system within a semiconductor processing tool.

7. The optoelectronic package according to claim 1 wherein the object is a semiconductor wafer.

8. The optoelectronic package according to claim 1 further comprising a black mask located on at least one of the lens and the photodiode element to absorb or trap light and thereby minimize stray light and its adverse effects.

9. An optoelectronic package for measuring the surface of an object, the optoelectronic package comprising:
a carrier;
a focal plane array located on the carrier and having a center point the focal plane array being adapted to identify varying light intensity based on optical interference;
a vertical-cavity surface-emitting laser (VCSEL) located at the center point of the focal plane array and directing light rays toward the object; and
a lens positioned between the VCSEL and the object, the lens adapted to receive the light rays from the VCSEL and create a ring of measured light which reflects off the surface of the object and the measured light is adapted to combine with a ring of reference light to produce optical interference on the focal plane array permitting the photodiode element to identify varying light intensity from the optical interference,
wherein variations in light intensity correspond to displacement, angular tip and tilt, or a combination thereof of the surface of the object.

10. The optoelectronic package according to claim 9 further comprising a computer system configured to engage with one or more components of the optoelectronic package.

11. The optoelectronic package according to claim 9 further comprising a thermoelectrically cooled configuration to reduce thermal noise in each photodiode element and remove heat generated by VCSEL.

12. The optoelectronic package according to claim 9 wherein the VCSEL is a microelectromechanical system (MEMS) tunable VCSEL.

13. The optoelectronic package according to claim 9 wherein the photodiode element has multiple concentric arc sections separated into three or more quadrants by gaps and separated from each other by open concentric rings.

14. The optoelectronic package according to claim 9 wherein the object is a motion system within a semiconductor processing tool.

15. The optoelectronic package according to claim 9 wherein the object is a semiconductor wafer.

16. The optoelectronic package according to claim 9 further comprising a black mask located on at least one of the lens and the photodiode element to absorb or trap light and thereby minimize stray light and its adverse effects.

17. An optical detection system comprising:
at least one light source;
an optical assembly configured to direct light from the at least one light source to a target;
a photodiode element arrangement positioned to receive light reflected or transmitted from the target, wherein the photodiode element arrangement comprises a focal plane array;
a black mask disposed over the focal plane array and configured to define one or more apertures through which light is received by the focal plane array;
processing electronics operatively coupled to the photodiode element arrangement and configured to generate output signals indicative of the received light; and
a computer system operatively coupled to the processing electronics and configured to process the output signals to determine at least one characteristic of the target and to output a result indicative of the at least one characteristic of the target.
